(19) United States
(12) Patent Application Publication
(10) Pub. No.: US 2018/0084635 A1
(43) Pub. Date: Mar. 22, 2018

(54) MULTILAYER SUBSTRATE FOR A LIGHT EMITTING SEMI-CONDUCTOR DEVICE PACKAGE

(71) Applicant: 3M INNOVATIVE PROPERTIES COMPANY, St. Paul, MN (US)

(72) Inventor: Ravi Palaniswamy, Singapore (SG)

(21) Appl. No.: 15/554,251

(22) PCT Filed: Feb. 18, 2016
(86) PCT No.: PCT/US2016/018401

§ 371 Date: Aug. 29, 2017

Related U.S. Application Data
(60) Provisional application No. 62/135,803, filed on Mar. 20, 2015.

(51) Int. Cl. H05K 1/02; H01L 33/64; H05K 1/18; H05K 1/11

(52) U.S. Cl. CPC H05K 1/0209; H05K 1/0207; H01L 33/642; H05K 1/189; H05K 2201/10106; H05K 2201/0162; H05K 2201/09827; H05K 2201/09681; H05K 1/111

(57) ABSTRACT

A flexible multilayer substrate for attaching a light emitting semiconductor device includes a first dielectric layer, a circuit layer on the first dielectric layer; a first thermally conductive layer on the circuit layer; a discontinuous metal support layer having a plurality of openings therethrough disposed on the first thermally conductive layer, and a second thermally conductive layer on the support layer. The flexible multilayer substrate further includes a plurality of conductive vias extending through the first dielectric layer such that the circuit layer is in communication with the plurality of conductive vias. The first and second thermally conductive layers are in contact within said openings.

### BACKGROUND

### Field of the Invention

Light emitting semi-conductor devices (LESD), including light emitting diodes (LEDs) and laser diodes can generate a substantial amount of heat during operation that must be properly managed or the performance of these devices can be limited or become inefficient. In general, LESDs are prone to damage caused by buildup of heat generated from within the devices, as well as heat from sunlight in the case of outside lighting applications, if the heat is not properly managed. Excessive heat buildup can deteriorate the materials used in the LESDs, such as encapsulants. When LESDs are attached to flexible-circuit laminates, which can also include other electrical components, the heat dissipation problems are greatly increased.

Cost effective thermal management for surface mount (SM) LESDs is a significant challenge facing the electronics industries today. SM LESDs must be provided with a die level thermal management solution as well as a drive circuit thermal management solution. Conventional SM LESD packaging solutions put the drive circuitry on either an FR4 printed circuit board (PCB) or a metal core PCB (MCPCB). In general, both of these substrates can include relatively thick dielectric layer which can reduce the thermal dissipation capability of the resulting devices. In some cases the flexible circuits are used for LESDs. These flexible circuit packages are commonly attached to an aluminum heat sink using either double-sided adhesive or the thermal melt adhesive. However, these adhesives can increase the thermal impedance of the package and decrease the efficiency of the LESDs. Consequently, there is a continuing need to improve the design of flexible multilayer substrates of LESD packaging in order to improve their thermal dissipation properties.

### SUMMARY

According to a first embodiment of the present invention, a flexible multilayer substrate for attaching a light emitting semiconductor device includes a first dielectric layer having a first side and a second side, a circuit layer disposed on the second side of the first dielectric layer; a first thermally conductive layer disposed on the circuit layer opposite the first dielectric layer; a discontinuous metal support layer disposed on the first thermally conductive layer opposite the circuit layer, and a second thermally conductive layer disposed on the support layer opposite the first thermally conductive layer. The flexible multilayer substrate further includes a plurality of conductive vias extended from the first side to the second side of the first dielectric layer wherein the circuit layer is in communication with the plurality of conductive vias. The discontinuous metal support layer is electrically continuous and includes an array of openings extending through the discontinuous metal support layer such that the second thermally conductive layer is in contact with the first thermally conductive layer in the openings through the discontinuous metal support layer.

In a second exemplary aspect, a flexible multilayer substrate for attaching a light emitting semiconductor device comprises a flexible circuit structure having a first dielectric layer having a first side and a second side, a plurality of conductive vias extending from the first side to the second side of the first dielectric layer, and a circuit layer disposed on the second side of the first dielectric layer; and an isolation structure configured to protect the circuit layer and attach the flexible circuit structure to an auxiliary substrate. The isolation structure comprises a first thermally conductive layer, a discontinuous metal support layer disposed on the first thermally conductive layer opposite the circuit layer, wherein the discontinuous metal support layer is electrically continuous and includes an array of openings extending through the discontinuous metal support layer; and a second thermally conductive layer disposed on the support layer opposite the first thermally conductive layer, wherein the second thermally conductive layer is in contact with the first thermally conductive layer in the openings through the discontinuous metal support layer.

The above summary of the present invention is not intended to describe each illustrated embodiment or every implementation of the present invention. The figures and the detailed description that follows more particularly exemplify these embodiments.

### BRIEF DESCRIPTION OF THE DRAWINGS

The present invention will be further described with reference to the accompanying drawings, wherein:

FIG. 1 is a schematic diagram of a flexible multilayer substrate for attaching a light emitting semiconductor device according to an embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the invention as defined by the appended claims.

### DETAILED DESCRIPTION OF THE EMBODIMENTS

In the following description, reference is made to the accompanying set of drawings that form a part of the description hereof and in which are shown by way of illustration several specific embodiments. It is to be understood that other embodiments are contemplated and can be made without departing from the scope or spirit of the present invention. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

Unless otherwise indicated, the terms “coat,” “coating,” “coated,” and the like are not limited to a particular type of application method such as spray coating, dip coating, flood coating, etc., and can refer to a material deposited by any method suitable for the material described, including deposition methods such vapor deposition methods, plating methods, coating methods, etc.

The term “LESD” means light emitting semiconductor devices, including light emitting diode device(s) and laser diode device(s); an LESD can be a bare LES die construction, a complete packaged LES construction, or an intermediate LES construction comprising more than the bare die, but less than all the components for a complete LES package, such that the terms LES and LESD can be used interchangeably and refer to one or all of the different LES constructions; a “discrete LESD” typically refers to one or more LESDs that are “packaged” and ready to function once connected to an electrical source, such as driving circuits including MCPCBs, MISs, etc. Examples of discrete LESDs that can be suitable for use in embodiments of the present invention Golden DRAGON LEDs, available from OSRAM Opto Semiconductors GmbH, Germany; LUXEON LEDs, available from Philips Lumileds Lighting Company, USA; and XLAMP LEDs, available from Cree, Inc., USA, as well as the discrete LESDs described herein and similar devices.

“Flexible multilayer substrate” means a circuitized flexible article to which one or more discrete LESDs can be attached that provides thermal management and drive circuitry for the LESDs attached thereto; commercially available alternatives to the support article of the present invention can include metal core printed circuit boards (MCPCBs), metal insulation substrates (MIS), Bergquist thermal boards, and COOLAM thermal substrates.

Exemplary embodiments of the present invention as described herein can pertain to a flexible multilayer substrate comprising metal filled vias, which extend all the way through a first dielectric layer, thereby providing an electrical and thermally conductive pathway through the first dielectric layer. The exemplary flexible multilayer substrate is a one metal layer design that can be utilized for a single LESD or a multiple LESD packaging.

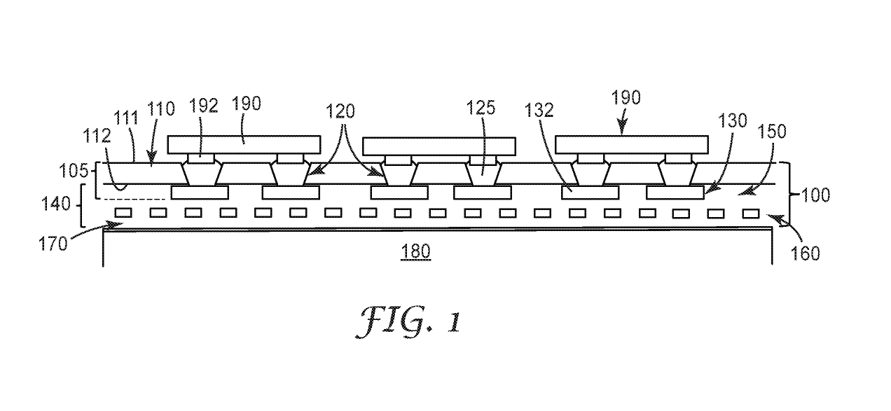

An exemplary flexible multilayer substrate for LESD packaging applications is shown in FIG. 1. Flexible multilayer substrate 100 includes a circuit portion 105 and an isolation structure 140 disposed on the circuit portion. The circuit portion includes a first dielectric layer 110 having a first side 111 and a second side 112 having a plurality of conductive vias 120 extending through the first dielectric layer from the first side 111 to the second side 112 and a circuit layer 130 disposed on the second side of the first dielectric layer that includes patterned conductive features or traces 132. The isolation structure 140 can be disposed on the circuit layer opposite the first dielectric layer. The isolation layer protects the circuit layer and enables the attachment of the flexible multilayer substrate to an auxiliary substrate, such as a heat spreader or a heat sink 180.

Circuit layer 130 can be formed of copper, silver plated copper, gold plated copper, gold or other suitable material which is formed on second side of the first dielectric layer. The circuit layer can be formed by either a conventional additive process, subtractive process or hybrid process.

Isolation structure 140 includes a first thermally conductive layer 150, a discontinuous metal support layer 160 disposed on the first thermally conductive layer, and a second thermally conductive layer 170 disposed on the support layer opposite the first thermally conductive layer. The isolation structure 140 is attached to circuit portion 105 such that the first thermally conductive layer is adjacent to the circuit layer. The discontinuous metal support layer is electrically continuous and includes an array of openings extending through the metal support layer such that the second thermally conductive layer is in contact with the first thermally conductive layer in the openings through the discontinuous metal support layer.

An LESD 190 can be attached, directly, or indirectly, to the top surface of via 120 on the first side 111 of the first dielectric layer 110 by a known die bonding methods such as eutectic, solder, electrically conductive adhesive, welding, and fusion bonding. In an exemplary aspect, LESD 190 includes a plurality of contacts 192 on a bottom side of the LESD wherein each of the plurality of contacts is directly bonded to a domed surface of a conductive via plug disposed in the via through the first dielectric layer. Vias 120 typically provide at least an electrical connection to circuit layer 130 and can optionally provide a thermal connection for heat dissipation. In some embodiments, thermally conductive encapsulant (not shown) can be dispensed between the LESD and the first dielectric layer and the conductive vias to enhance thermal transfer of heat away from the LESD.

In an exemplary aspect, the first dielectric layer 110 is a flexible polymer film or other suitable material having a thickness of from about 0.5 mils to about 5.0 mils. Suitable materials for the first dielectric layer include polyesters, polycarbonates, liquid crystal polymers, and polyimides. Polyimides are preferred. Suitable polyimides include those available under the trade names KAPTON, available from DuPont; APICAL, available from Kaneka Texas corporation; SKC Kolon PI, available from SKC Kolon PI Inc.; and UPILEX and UPISEL, available from Ube-Nitto Kasei Industries, Japan. Most preferred are polyimides available under the trade designations UPILEX S, UPILEX SN, and UPISEL VT, all available from Ube-Nitto Kasei Industries. These polyimides are made from monomers such as biphenyl tetracarboxylic dianhydride (BBDA) and phenyl diamine (PDA). In at least one embodiment, the thickness of the dielectric layer is preferably 50 micrometers or less, but can be any thickness suitable for a particular application.

The first dielectric layer can be initially clad on one side with a conductive layer. The conductive layer can be formed into the drive circuitry for the LESDs to be mounted on the flexible multilayer substrate by a subtractive etch process. Alternatively, a photo-imageable layer can be disposed on the one side of the first dielectric layer. The photo-imageable layer can be patterned and developed to enable the drive circuitry to be formed on the first dielectric layer by an additive plating process. The conductive layers can be any suitable material including copper, gold, nickel/gold, silver, and stainless steel, but are typically copper. The conductive layer can be applied in any suitable manner such as sputtering, plating, chemical vapor deposition, or it can be laminated to the dielectric layer or attached with an adhesive.

Vias 120 extend through dielectric layer 110 and can be any suitable shape, e.g., circular, oval, rectangular, or the like. The vias can be formed in the first dielectric layer using any suitable method such as chemical etching, plasma etching, focused ion-beam etching, laser ablation, embossing, microreplication, injection molding, and punching. Chemical etching can be preferred in some embodiments. Any suitable etchant can be used and can vary depending on the type of dielectric layer material being used. Suitable etchants can include alkali metal salts, e.g. potassium hydroxide; alkali metal salts with one or both of solubilizers, e.g., amines, and alcohols, such as ethylene glycol. Suitable chemical etchants for some embodiments of the present invention include KOH/ethanol amine/ethylene glycol etchants such as those described in more detail in U.S. Patent Publication No. 2007-0120089-A1, incorporated herein by reference. Other suitable chemical etchants for some embodiments of the present invention include a KOH/glycine etchants such as those described in more detail in co-pending U.S. Patent Publication No. 2013-0207031, incorporated herein by reference. Subsequent to etching, the dielectric layers can be treated with an alkaline KOH/potassium permanganate (PPM) solution, e.g., a solution of about 0.7 to about 1.0 wt. % KOH and about 3 wt. % KMnO₄.

The vias 120 can be formed with sloped or angled side walls such that each via 120 characterized by a first width at the first side of the first dielectric layer and a second width at the second side of the first dielectric layer. For purposes of this application, a sloped side wall means that the side walls are not perpendicular to the horizontal plane of the first dielectric layer. In an exemplary aspect, the first width can be greater than the second width. The side walls of the vias slopes away from surface of the second side of the first dielectric layer at an angle from about 20 degrees to about 80 degrees, preferably at an angle of from about 20° to about 45°, and more preferably at an angle of from about 25° to about 35°.

The sloped side walls of vias 120 can contain more conductive material than a via having 90° side walls. For example, the opening of a via adjacent a conductive feature 132 on the second side 112 of the dielectric layer 110 will typically be limited by the size of that conductive feature; however, by employing sloped via side walls, the opening at the opposing end of the via (i.e. at the first side 111 of the dielectric layer) can be enlarged to an optimum size such that the via can contain a larger amount of conductive material (to transfer more heat away from the LESD) and the conductive at this opening has a large surface area that can interface more effectively with a heat transferring or absorbing material, such as a thermal conductive potting material or a metal substrate, which can be attached to the dielectric layer and conductive-filled vias. Additionally, the larger surface area of the vias enables easing in the placement tolerances of the LESDs on the flexible multilayer substrate 100. Finally, the slope of the vias walls aids in retaining the solder during the solder reflow process preventing the flowing of the solder to adjacent solder pads.

Each via 120 includes a conductive material disposed therein. The conductive material forms via plug 125 that substantially fills the via. The via plug can extend from the second side of the first dielectric layer where it connects circuit layer 130 to a position at or near the first side of the first dielectric layer and can have a domed surface disposed adjacent to the first side of the first dielectric layer. Via plug can generally be described as a frustum (the solid of a cone between two parallel planes) shaped metal feature with a slightly domed surface, or slight bowl shape (i.e., the center is concave), near the first side of the first dielectric layer. In an exemplary aspect a portion of the domed surface can rise above the plane defined by the surface of the first side of the first dielectric layer.

Conductive via plug 125 can be formed of a high temperature tin-lead solder, plated copper, plated nickel, or another electrically conductive material that meets the conductivity and mechanical requirements of the selected application. In one exemplary aspect, the conductive via plug can be formed by additively plating metal into the opening from the first side of the first dielectric layer. Alternatively, a solder reflow process can be used to form the conductive via plug. The conductive vias enable a reliable electrical connection of LESD 190 to the circuit layer 130 of the flexible multilayer substrate.

In one exemplary aspect, the discontinuous metal support layer of the isolation structure can be a flexible heat-spreading material such as a perforated metal foil, a metal mesh and the like. In a support layer composed of a flexible heat-spreading material, heat can spread laterally such that there will be a larger thermal transfer area on the second side of the discontinuous metal support layer which can increase and improve heat transfer efficiency associated with the discontinuous metal support layer and the overall thermal performance of the flexible multilayer substrate. Depending on the particular embodiment, heat may be transferred from the support layer via conduction in the Z direction to the second thermally conductive layer.

Flexible heat-spreading materials may generally refer to and include a wide range of metallic materials having flexibility equal to or greater than a sheet of stamped aluminum having a thickness of 20 mils and/or flexibility equal to or greater than a sheet of stamped copper having a thickness of 15 mils, etc.

In an exemplary aspect, the discontinuous metal support layer is perforated such that it has a continuous thermally and electrically conductive metallic matrix portion having a regular array of openings disposed therethrough. The first thermally conductive layer and the second thermally conductive layer can be in direct contact through the openings in the discontinuous metal support layer. In one exemplary aspect where the first thermally conductive layer and the thermally conductive layer are formed of the same thermally conductive material, the thermal interface between the first thermally conductive layer and the thermally conductive layer can be eliminated within openings in the support layer which can improve the thermal transfer performance of a flexible multilayer substrate having a perforated support layer.

The first and/or the second thermally conductive layer can be any suitable insulating thermal interface material. Generally, thermal interface materials comprise fillers that are thermally conductive, but not electrically conductive disposed in a polymeric binder. Exemplary thermally conductive fillers an include boron nitride, aluminum oxide, magnesium oxide, crystalline silicon dioxide, silicon nitride, aluminum nitride, silicon carbide, zinc oxide and the like, while exemplary polymeric binders can include silicone binders, epoxy binders, acrylic binders, etc. The thermally conductive layers can be can be applied to the flexible multilayer substrate as a liquid, paste, gel, solid, etc. Suitable methods for applying thermal interface material depend on the properties of the specific thermal interface material, but include precision coating, dispensing, screen printing, lamination etc.

In an alternative aspect, the isolation structure can be pre-formed and laminated to the flexible circuit structure in a piecewise or continuous roll to roll process. Suitable methods for curing a curable thermal interface material include UV curing, thermal curing etc.

In an exemplary aspect, the first thermally conductive layer can be a thermal bonding, thermally conductive adhesive that can be used to bond the isolation structure over the circuit layer of the flexible circuit structure. In another aspect, the second thermally conductive layer can be a thermal bonding, thermally conductive adhesive that can be used to bond the flexible multilayer substrate to the base of a heat sink or other heat spreader. In an alternative aspect, first thermally conductive layer and/or the second thermally conductive layer do not have to have adhesive properties in which case an auxiliary thermally conductive adhesive can be used to bond the isolation structure to the flexible circuit structure of the flexible multilayer substrate and/or to bond the flexible multilayer substrate to a heat sink or other heat spreader.

The flexible multilayer substrate can provide the following benefits when used in LESD packaging applications. The flexible multilayer substrate of the present invention can reduce the overall thermal resistance of a discrete light emitting device. The vias of the present invention containing conductive material provide excellent Z-axis thermal conductivity. The size of the vias, porosity of the discontinuous metal support layer of the isolation structure can be tailored to provide optimized thermal resistance values. Because the flexible multilayer substrate is a single metal layer structure, the flexible multilayer substrate can provide a less expensive substrate for use in LESD packaging application without compromising thermal performance when compared to a two metal layer substrate. In addition, the flexible multilayer substrate of the present invention with LESDs can eliminate the cost associated with conventional LED submounts. The flexible LESDs of the present invention can provide a robust, cost-effective thermal management solution for current and future high power LESD constructions.

Various modifications, equivalent processes, as well as numerous structures to which the present invention can be applicable will be readily apparent to those of skill in the art to which the present invention is directed upon review of the present specification.

We claim:

1. A flexible multilayer substrate for attaching a light emitting semiconductor device comprising:
a first dielectric layer having a first side and a second side;
a plurality of conductive vias extending from the first side to the second side of the first dielectric layer;
a circuit layer disposed on the second side of the first dielectric layer in communication with the plurality of conductive vias;
a first thermally conductive layer disposed on the circuit layer opposite the first dielectric layer;
a discontinuous metal support layer disposed on the first thermally conductive layer opposite the circuit layer, wherein the discontinuous metal support layer is electrically continuous and includes an array of openings extending through the discontinuous metal support layer; and
a second thermally conductive layer disposed on the support layer opposite the first thermally conductive layer, wherein the second thermally conductive layer is in contact with the first thermally conductive layer in the openings through the discontinuous metal support layer.

2. The flexible multilayer substrate of claim 1, wherein the vias are filled with plated copper to form a via plug wherein the via plug has a domed surface that extends above the first surface of the first dielectric layer.

3. The flexible multilayer substrate of claim 1, wherein the first thermally conductive layer comprises a thermally conductive filler disposed in a binder.

4. The flexible multilayer substrate of claim 1, wherein the first thermally conductive layer is a thermal bonding, thermally conductive adhesive.

5. The flexible multilayer substrate of claim 1, wherein the first thermally conductive layer and the second thermally conductive layer have the same composition.

6. The flexible multilayer substrate of claim 2, wherein the light emitting semiconductor device is attached flexible multilayer substrate adjacent to the first side of the first dielectric layer.

7. The flexible multilayer substrate of claim 2, wherein the light emitting semiconductor device includes a plurality of contacts on a bottom side of the light emitting semiconductor device wherein each of the plurality of contacts is directly bonded to a domed surface of a conductive via plug disposed in the via through the first dielectric layer.

8. The flexible multilayer substrate of claim 1, wherein the discontinuous metal support layer is selected from one of a perforated metal foil and a metal mesh that serves as an intermediate heat spreader.

9. The flexible multilayer substrate of claim 1, wherein the first thermally conductive layer and the thermally conductive layer are the same material and there is no thermal interface between the first thermally conductive layer and the thermally conductive layer within openings in the support layer.

10. A flexible multilayer substrate for attaching a light emitting semiconductor device comprising:
a flexible circuit structure having a first dielectric layer having a first side and a second side, a plurality of conductive vias extending from the first side to the second side of the first dielectric layer, and a circuit layer disposed on the second side of the first dielectric layer; and
an isolation structure configured to protect the circuit layer and attach the flexible circuit structure to an auxiliary substrate, wherein the isolation structure comprises a first thermally conductive layer, a discontinuous metal support layer disposed on the first thermally conductive layer opposite the circuit layer, wherein the discontinuous metal support layer is electrically continuous and includes an array of openings extending through the discontinuous metal support layer; and a second thermally conductive layer disposed on the support layer opposite the first thermally conductive layer, wherein the second thermally conductive layer is in contact with the first thermally conductive layer in the openings through the discontinuous metal support layer.
